(19) United States
(12) Patent Application Publication
(10) Pub. No.: US 2026/0182204 A1
(43) Pub. Date: Jun. 25, 2026

(54) DISPLAY DEVICE AND ELECTRONIC DEVICE COMPRISING THE SAME

(71) Applicant: Samsung Display Co., Ltd., Yongin-si (KR)

(72) Inventor: Yoon A KIM, Yongin-si (KR)

(21) Appl. No.: 19/345,617

(22) Filed: Sep. 30, 2025

(30) Foreign Application Priority Data
Dec. 19, 2024 (KR) 10-2024-0191341

(51) Int. Cl. H10K 59/80; G02B 27/01; H10K 50/19

(52) U.S. Cl. CPC H10K 59/80518; G02B 27/017; H10K 50/19; H10K 59/80521; G02B 2027/0178

(57) ABSTRACT

A display device includes: a substrate on which a display area is defined; a reflective electrode on the substrate; an optical auxiliary layer on the reflective electrode; a first electrode on the optical auxiliary layer; a light emitting stack on the first electrode; a second electrode on the light emitting stack; and a third electrode on the second electrode, wherein the third electrode includes: a first main portion on the second electrode; and a first protrusion protruding from the first main portion.

### CROSS-REFERENCE TO RELATED APPLICATION

The present application claims priority to and the benefit of Korean Patent Application No. 10-2024-0191341, filed on Dec. 19, 2024, in the Korean Intellectual Property Office, the entire disclosure of which is incorporated herein by reference.

### BACKGROUND

### 1. Field

Aspects of some embodiments of the present disclosure relate to a display device and an electronic device comprising the same.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is located on a semiconductor wafer substrate including complementary metal oxide semiconductor (CMOS).

The above information disclosed in this Background section is only for enhancement of understanding of the background and therefore the information discussed in this Background section does not necessarily constitute prior art.

### SUMMARY

Aspects of some embodiments of the present disclosure include a display device capable of providing high-resolution images.

Aspects of some embodiments of the present disclosure may also include a head mounted display capable of providing high-resolution images.

However, aspects of some embodiments of the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes a substrate on which a display area is defined, a reflective electrode located on the substrate, an optical auxiliary layer located on the reflective electrode, a first electrode located on the optical auxiliary layer, a light emitting stack located on the first electrode, a second electrode located on the light emitting stack, and a third electrode located on the second electrode. According to some embodiments, the third electrode comprises a first main portion located on the second electrode and a first protrusion protruding from the first main portion.

According to some embodiments of the present disclosure, the first main portion comprises an eleventh main portion, a twelfth main portion, and an eleventh bent portion located between the eleventh main portion and the twelfth main portion and connecting the eleventh main portion and the twelfth main portion to each other. The first protrusion may protrude from the eleventh bent portion.

According to some embodiments of the present disclosure, the third electrode further comprises a second main portion located on the second electrode and a second protrusion protruding from the second main portion. According to some embodiments, the first protrusion is arranged to be connected to a top surface of the eleventh bent portion and may protrude into a region located between the first main portion and the second main portion.

According to some embodiments of the present disclosure, the first main portion further comprises a thirteenth main portion and a twelfth bent portion located between the twelfth main portion and the thirteenth main portion and connecting the twelfth main portion and the thirteenth main portion to each other.

According to some embodiments of the present disclosure, the twelfth bent portion is connected to one side of the thirteenth main portion, and the first main portion further comprises a thirteenth bent portion connected to the other side of the thirteenth main portion.

According to some embodiments of the present disclosure, the light transmittance of the second electrode is greater than that of the third electrode, and the light reflectivity of the third electrode may be greater than that of the second electrode.

According to some embodiments of the present disclosure, the display area comprises a first region corresponding to a first portion of the display area and a second region corresponding to a second portion of the display area. According to some embodiments, the first main portion comprises an eleventh bent portion, a twelfth bent portion, and a twelfth main portion located between the eleventh bent portion and the twelfth bent portion. According to some embodiments, the first protrusion comprises a first side surface having a selected angle with the twelfth main portion and a second side surface having a selected angle with the twelfth main portion. According to some embodiments, the selected angle between the first side surface of the first protrusion and the twelfth main portion may be different in the first region and the second region.

According to some embodiments of the present disclosure, in the first region, the first side surface of the first protrusion has a first angle with the twelfth main portion, and in the second region, the first side surface of the first protrusion has a second angle with the twelfth main portion. According to some embodiments, the first angle may be greater than the second angle.

According to some embodiments of the present disclosure, the first region may be positioned closer to the center of the display area than the second region.

According to some embodiments of the present disclosure, the first angle and the second angle may be acute angles.

According to some embodiments of the present disclosure, in the first region, the second side surface of the first protrusion has a third angle with the twelfth main portion, and in the second region, the second side surface of the first protrusion has a fourth angle with the twelfth main portion. According to some embodiments, the third angle may be less than the fourth angle.

According to some embodiments of the present disclosure, the third angle and the fourth angle may be obtuse angles.

According to some embodiments of the present disclosure, the third electrode may comprise an opening arranged to overlap the second electrode.

According to some embodiments of the present disclosure, the display area comprises a first region corresponding to a first portion of the display area and a second region corresponding to a second portion of the display area. According to some embodiments, the first main portion comprises an eleventh bent portion, a twelfth bent portion, and a twelfth main portion located between the eleventh bent portion and the twelfth bent portion. An area of a region where the first protrusion overlaps the second electrode in a plane direction of the display area may be different in the first region and the second region.

According to some embodiments of the present disclosure, an area of a region where the first protrusion overlaps the second electrode in a plane direction of the display area may be smaller in the first region than in the second region.

According to some embodiments of the present disclosure, an electronic device comprises a processor providing an image signal, a display module receiving the image signal from the processor to display an image, and a power module supplying power to the display module. According to some embodiments, the display module comprises a substrate on which a display area is defined, a reflective electrode located on the substrate, an optical auxiliary layer located on the reflective electrode, a first electrode located on the optical auxiliary layer, a light emitting stack located on the first electrode, a second electrode located on the light emitting stack, and a third electrode located on the second electrode. According to some embodiments, the third electrode comprises a first main portion located on the second electrode and a first protrusion protruding from the first main portion.

According to some embodiments of the present disclosure, a light transmittance of the second electrode is greater than that of the third electrode, and a light reflectivity of the third electrode may be greater than that of the second electrode.

According to some embodiments of the present disclosure, the display area comprises a first region corresponding to a first portion of the display area and a second region corresponding to a second portion of the display area. According to some embodiments, the first main portion comprises an eleventh bent portion, a twelfth bent portion, and a twelfth main portion located between the eleventh bent portion and the twelfth bent portion. According to some embodiments, the first protrusion comprises a first side surface having a selected angle with the twelfth main portion and a second side surface having a selected angle with the twelfth main portion. According to some embodiments, the selected angle between the first side surface of the first protrusion and the twelfth main portion may be different in the first region and the second region.

According to some embodiments of the present disclosure, in the first region, the first side surface of the first protrusion has a first angle with the twelfth main portion, and in the second region, the first side surface of the first protrusion has a second angle with the twelfth main portion. According to some embodiments, the first angle may be greater than the second angle.

According to some embodiments of the present disclosure, the third electrode may comprise an opening arranged to overlap the second electrode.

When a lens is located on a color filter to perform a light collecting function, the emitted light may pass through an encapsulation film or the like, which may deteriorate the luminance in user's both eyes. Further, there may be a disadvantage in that the thickness of the entire display device increases due to the arrangement of the lens. Thus, according to some embodiments of the present disclosure, the lens is removed and a third electrode is placed to perform a light collecting function, which may prevent or reduce an increase in the thickness of the display device, and reduce the luminance deterioration of the display device. According to some embodiments, the third electrode may be located on a second electrode. According to some embodiments, the protrusion of the third electrode may perform a reflection function relatively more than the second electrode.

According to some embodiments, in the third electrode, if the main portion including the protrusion is entirely formed on the second electrode, a problem that light emitted from a light emitting stack does not pass through the third electrode may occur. Thus, according to some embodiments, an opening is separately formed in the third electrode to easily adjust the light direction and solve the problem of securing luminance.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is an exploded perspective view showing a display device according to some embodiments of the present disclosure;

FIG. 2 is a block diagram showing a display device according to some embodiments of the present disclosure;

FIG. 3 is an equivalent circuit diagram of a first sub-pixel according to some embodiments of the present disclosure;

FIG. 4 is a layout diagram illustrating an example of a display panel according to some embodiments of the present disclosure;

FIG. 5 is a layout diagram showing an example of the display area of FIG. 4;

FIG. 6 is a layout diagram showing another example of the display area of FIG. 4;

FIG. 7 is a cross-sectional view illustrating aspects of a display panel taken along the line I1-I1′ of FIG. 5;

FIG. 8 is a cross-sectional view illustrating further details of a display panel taken along the line I1-I1′ of FIG. 5;

FIG. 9 is a cross-sectional view showing aspects of a display device according to some embodiments of the present disclosure;

FIG. 10 is a plan view showing aspects of a display panel according to some embodiments of the present disclosure;

FIG. 11 is a plan view showing aspects of a display panel according to some embodiments of the present disclosure;

FIG. 12 is a cross-sectional view taken along the line I-I′ of FIG. 11;

FIG. 13 is a plan view showing a display panel according to some embodiments of the present disclosure;

FIG. 14 is a cross-sectional view taken along the line II-II′ of FIG. 13;

FIG. 15 is a plan view showing a display panel according to some embodiments of the present disclosure;

FIG. 16 is a cross-sectional view taken along the line III-III′ of FIG. 15;

FIGS. 17 to 19 are plan views showing a display panel according to some embodiments of the present disclosure;

FIG. 20 is a flowchart showing aspects of a method of manufacturing a display panel according to some embodiments of the present disclosure;

FIGS. 21 to 24 are cross-sectional views illustrating aspects of a method of manufacturing a display panel according to some embodiments of the present disclosure;

FIG. 25 is a perspective view illustrating a head mounted display according to some embodiments of the present disclosure;

FIG. 26 is an exploded perspective view illustrating an example of the head mounted display of FIG. 25;

FIG. 27 is a perspective view illustrating a head mounted display according to some embodiments of the present disclosure;

FIG. 28 is a block diagram of an electronic device according to some embodiments of the present disclosure; and

FIG. 29 is schematic diagrams of electronic devices according to some embodiments of the present disclosure.

### DETAILED DESCRIPTION

The aspects and features of the embodiments disclosed herein, and methods of achieving them, will become more apparent upon reference to the embodiments described in detail with accompanying drawings. However, aspects of embodiments according to the present disclosure are not limited to the embodiments disclosed herein, but will be embodied in many different forms, and these embodiments are provided merely to make the disclosure complete and to fully inform one of ordinary skill in the art to which the invention according to the present disclosure belongs, and the invention according to the present disclosure is defined by the scope of the appended claims, and their equivalents.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are examples and are not intended to be limiting to those shown herein.

Although first, second, and the like are used to describe various components, the components are not limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Aspects of some embodiments will be described below with reference to the accompanying drawings. Configurations that function the same (or substantially the same) between embodiments are given the same drawing designation and some repeated description may be omitted.

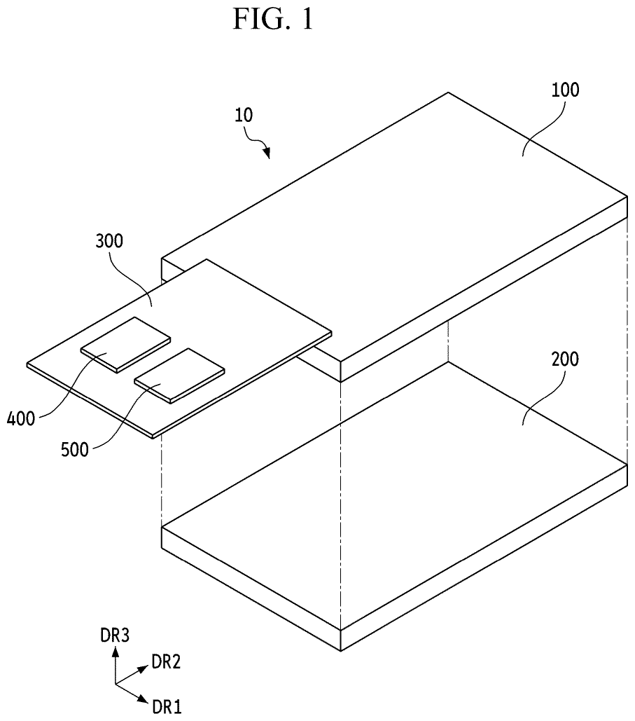

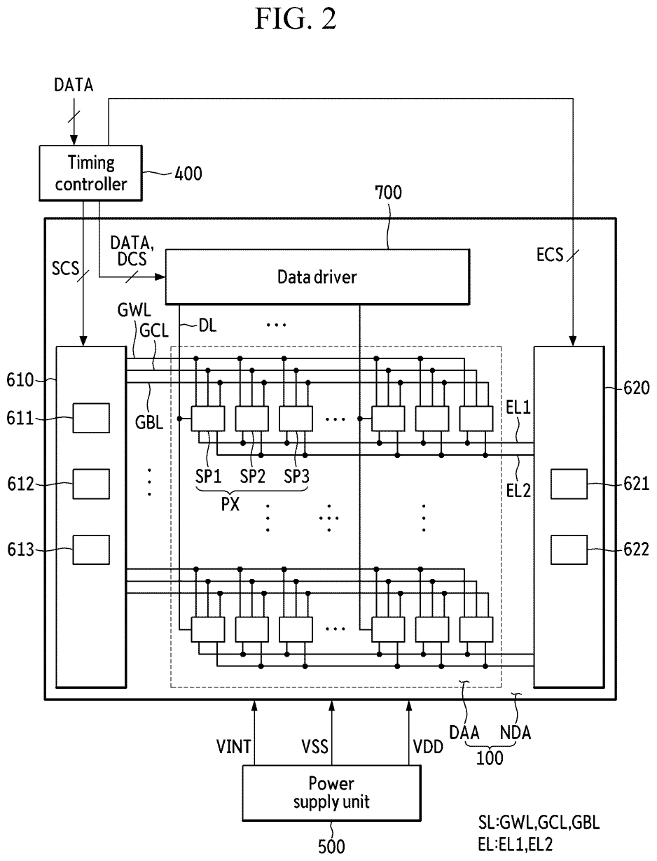

FIG. 1 is an exploded perspective view showing a display device according to some embodiments of the present disclosure. FIG. 2 is a block diagram showing a display device according to some embodiments of the present disclosure.

Referring to FIGS. 1 and 2, a display device 10 according to some embodiments is a device configured to display moving images (e.g., video images) or still images (e.g., static images). The display device 10 according to some embodiments may be applied to portable electronic devices such as mobile phones, smartphones, tablet personal computers, mobile communication terminals, electronic organizers, electronic books, portable multimedia players (PMPs), navigation systems, ultra mobile PCs (UMPCs) or the like. For example, the display device 10 according to some embodiments may be applied as a display unit of a television, a laptop, a monitor, a billboard, or an Internet-of-Things (IoT) terminal. Alternatively, the display device 10 according to some embodiments may be applied to smart watches, watch phones, head mounted displays (HMDs) for implementing virtual reality and augmented reality, and the like.

The display device 10 according to some embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, an irregular shape, a circular shape, or an elliptical shape. The planar shape of the display device 10 may conform to the planar shape of the display panel 100, but the embodiments of the present disclosure are not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA configured to display images and a non-display area NDA (e.g., surrounding, outside a footprint, or in a periphery of the display area DAA) not displaying images as shown in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

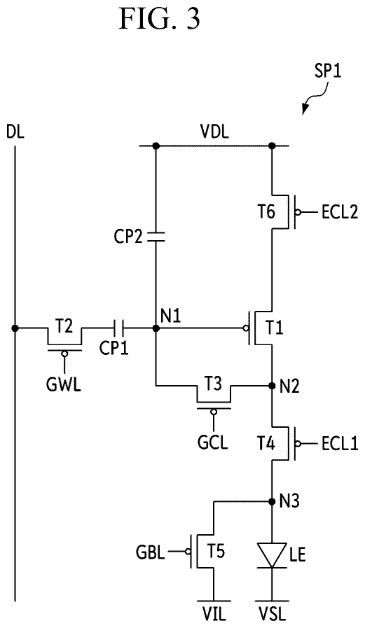

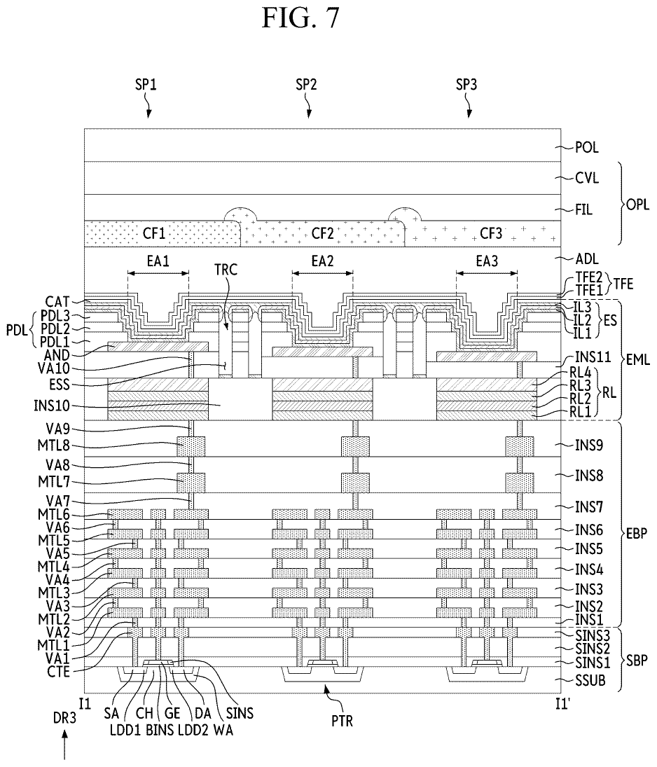

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and arranged on a semiconductor substrate SSUB (see FIG. 7). For example, the plurality of pixel transistors of the data driver 700 may be formed as complementary metal oxide semiconductor (CMOS) transistors, but the embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be located in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed as CMOS transistors, but the embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed as CMOS transistors, but the embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

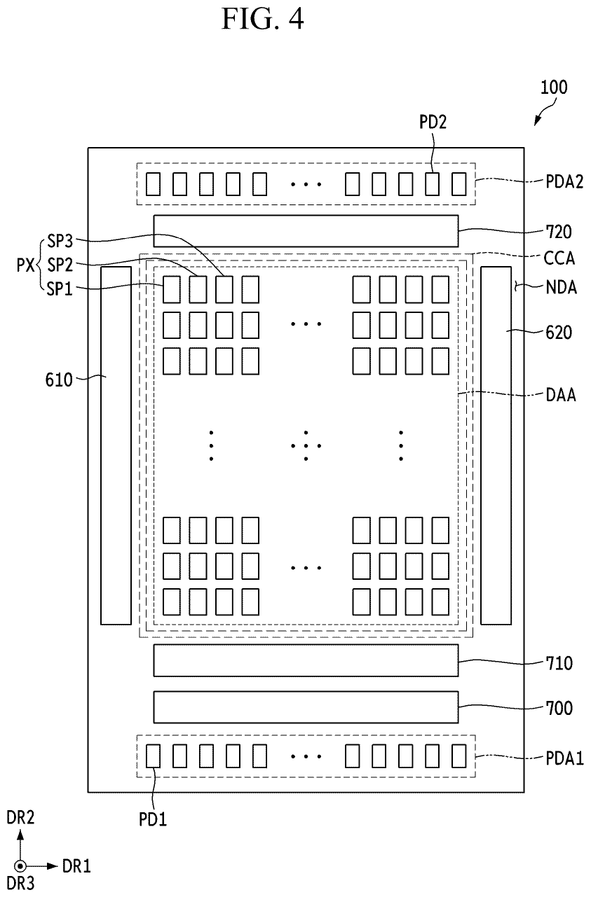

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed as CMOS transistors, but the embodiments of the present disclosure are not limited thereto. Each of the timing control circuit 400 and the power supply circuit 500 may be located between the data driver 700 and the first pad portion PDA1 (see FIG. 4).

FIG. 3 is an equivalent circuit diagram of a first sub-pixel according to some embodiments of the present disclosure. Although FIG. 3 illustrates various components in a sub-pixel according to some embodiments, embodiments according to the present disclosure are not limited thereto, and according to various embodiments, the sub-pixel may include additional components or fewer components without departing from the spirit and scope of embodiments according to the present disclosure.

Referring to FIG. 3, a first sub-pixel SP1 may be connected to the write scan line GWL, the control scan line GCL, the bias scan line GBL, the first emission control line ECL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer located between the first electrode and the second electrode, but the embodiments of the present disclosure are not limited thereto. For example, the light emitting element LE may be an inorganic light emitting element including a first electrode, a second electrode, and an inorganic semiconductor located between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode thereof according to a voltage applied to the gate electrode thereof.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 and a second node N2. The third transistor T3 is turned on by the write control signal of the write control line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a p-type MOSFET, but the embodiments of the present disclosure are not limited thereto. Each of the first to sixth transistors T1 to T6 may be an n-type MOSFET. Alternatively, some of the first to sixth transistors T1 to T6 may be p-type MOSFETs, and each of the remaining transistors may be an n-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to some embodiments of the present disclosure.

Referring to FIG. 4, the display area DAA of the display panel 100 according to some embodiments includes the plurality of pixels PX arranged in a matrix form. The non-display area NDA of the display panel 100 according to some embodiments includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. However, the embodiments of the present disclosure are not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

A cathode connection portion CCA may be a region in which a second electrode CAT (see FIG. 7) of a display element layer EML (see FIG. 7) is connected to the first driving voltage line VSL of the non-display area NDA. The cathode connection portion CCA may be located outside at least one side of the display area DAA. For example, the cathode connection portion CCA may be located outside at least on one side among the left side, the right side, the upper side, and the lower side of the display area DAA. Alternatively, the cathode connection portion CCA may be located to surround the display area DAA as shown in FIG. 4 in order to minimize a deviation in the first driving voltage VSS due to a voltage drop (IR drop) or voltage rise (IR rising) of the second electrode CAT in the display area DAA.

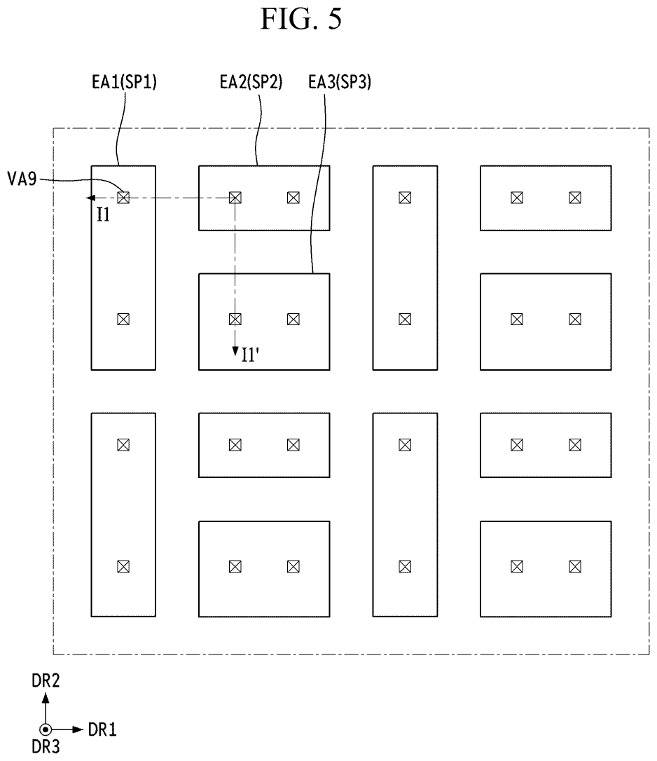

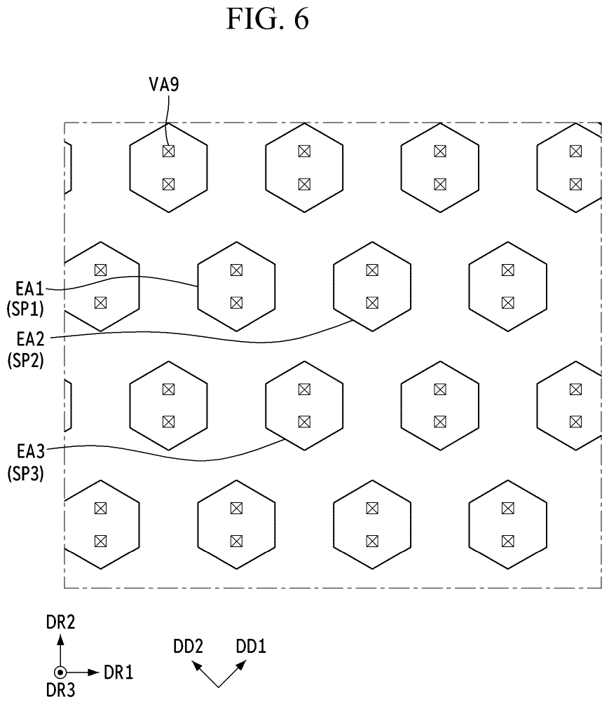

FIG. 5 is a layout diagram showing an example of the display area of FIG. 4. FIG. 6 is a layout diagram showing another example of the display area of FIG. 4.

Referring to FIGS. 5 and 6, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in plan view, a quadrilateral or hexagonal shape as shown in FIGS. 5 and 6, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 6, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 6.

FIG. 7 is a cross-sectional view illustrating an example of a display panel taken along the line I1-I1′ of FIG. 5.

Referring to FIG. 7, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be located on the semiconductor substrate SSUB. A second semiconductor insulating film SINS2 may be located on the first semiconductor insulating film SINS1.

The plurality of contact terminals CTE may be located on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may include any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed as a silicon carbonitride (SiCN) or silicon oxide (SiOₓ)-based inorganic film, but the present disclosure is not limited thereto.

The semiconductor substrate SSUB may be replaced with a glass substrate or a polymer resin substrate such as polyimide. In this case, thin film transistors may be arranged on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of insulating films INS1 to INS11. In addition, the light emitting element backplane EBP includes a plurality of insulating films INS1 to INS9 located between the first to eighth conductive layers ML1 to ML8.

The first to eighth insulating films INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 3.

For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may include substantially the same material. The first to eighth conductive layers ML1 to ML8 and the first to eighth vias VA1 to VA8 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include substantially the same material. First to eighth insulating films INS1 to INS8 may be formed as silicon oxide (SiOₓ)-based inorganic films, but the embodiments of the present disclosure are not limited thereto.

A ninth insulating film INS9 may be located on the eighth insulating film INS8 and the eighth conductive layer ML8. The ninth insulating film INS9 may be formed as a silicon oxide (SiOₓ)-based inorganic film, but the embodiments of the present disclosure are not limited thereto.

Each of the ninth vias VA9 may penetrate the ninth insulating film INS9 and be connected to the exposed eighth conductive layer ML8. The ninth vias VA9 may include any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be located on the light emitting element backplane EBP. The display element layer EML may include tenth and eleventh insulating films INS10 and INS11, a reflective electrode RL, the first electrodes AND, a light emitting stack IL, the second electrode CAT, a pixel defining film PDL, and a plurality of trenches TRC.

The reflective electrode RL may be located on the ninth insulating film INS9. The reflective electrode RL may include at least one reflective electrode RL1, RL2, RL3, and RL4. For example, the reflective electrode RL may include the first to fourth reflective electrodes RL1, RL2, RL3, and RL4 as shown in FIG. 7.

The first reflective electrodes RL1 may be located on the ninth interlayer insulating film INS9, and may be connected to the ninth via VA9. Each of the second reflective electrodes RL2 may be located on the first reflective electrode RL1 corresponding thereto. Each of the third reflective electrodes RL3 may be located on the second reflective electrode RL2 corresponding thereto. Each of the fourth reflective electrodes RL4 may be located on the third reflective electrode RL3 corresponding thereto.

Because the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be located on the ninth interlayer insulating film INS9. The tenth interlayer insulating film INS10 may be located between the reflective electrodes RL adjacent to each other. The tenth interlayer insulating film INS10 may be a film for flattening a stepped portion caused by the reflective electrodes RL. The eleventh interlayer insulating film INS11 may be located on the tenth interlayer insulating film INS10 and the reflective electrode RL.

The tenth interlayer insulating film INS10 and the eleventh interlayer insulating film INS11 may be formed as silicon oxide (SiOₓ)-based inorganic films, but the embodiments of the present disclosure are not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as shown in FIG. 7, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed ninth metal layer ML9. The tenth vias VA10 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be located on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is located.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed as silicon oxide (SiOₓ)-based inorganic films. Alternatively, the first pixel defining film PDL1 and the third pixel defining film PDL3 may be formed as silicon nitride (SiNₓ)-based inorganic films, whereas the second pixel defining film PDL2 may be formed as a silicon oxide (SiOₓ)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be located between the neighboring sub-pixels SP1, SP2, and SP3. Although FIG. 7 illustrates that two trenches TRC are located between the neighboring sub-pixels SP1, SP2, and SP3, the present disclosure is not limited thereto.

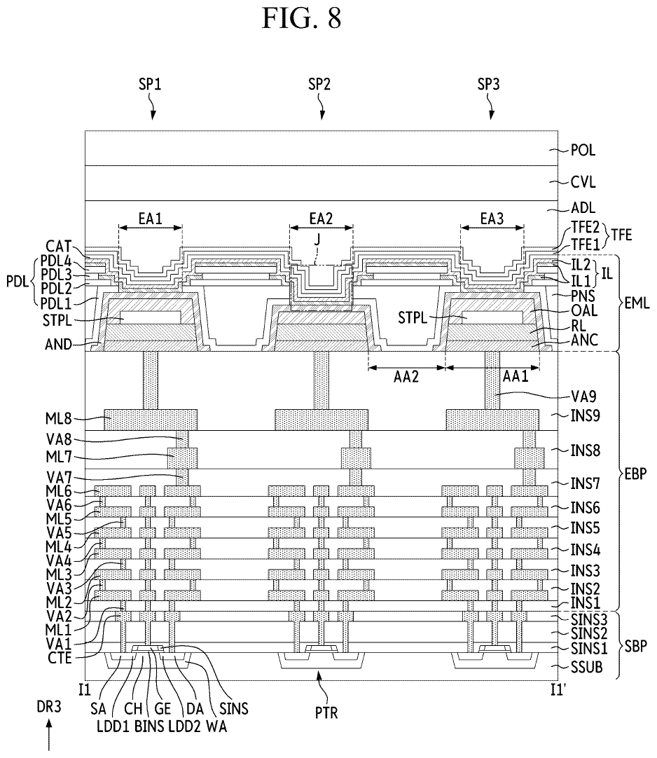

The light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but the present disclosure is not limited thereto. For example, the light emitting stack IL may have a two-tandem structure including two stack layers as shown in FIG. 8.

In the three-tandem structure, the light emitting stack IL may have a tandem structure including a plurality of intermediate layers IL1, IL2, and IL3 that emit different lights. For example, the light emitting stack IL may include the first stack layer IL1 that emits the first light, the second stack layer IL2 that emits the second light, and the third stack layer IL3 that emits the third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the first electrodes AND and the pixel defining film PDL, and a residual film RIL located on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be located on the first stack layer IL1. Due to the trench TRC, the second stack layer IL2 may be cut off between the neighboring sub-pixels SP1, SP2, and SP3. A cavity ESS or an empty space may be located between the residual film RIL and the second stack layer IL2 in the trench TRC. The third stack layer IL3 may be located on the second stack layer IL2. The third stack layer IL3 is not cut off by the trench TRC and may be located to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer located between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be located on the pixel defining film PDL.

In addition, FIG. 7 illustrates that the light emitting stack IL that emits light is located in the first emission area EA1, the second emission area EA2, and the third emission area EA3, but the present disclosure is not limited thereto. For example, instead of the light emitting stack IL, the first light emitting layer may be located in the first emission area EA1, and may be omitted from the second emission area EA2 and the third emission area EA3. Furthermore, the second light emitting layer may be located in the second emission area EA2 and may be omitted from the first emission area EA1 and the third emission area EA3. Furthermore, the third light emitting layer may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the light emitting stack IL. The second electrode CAT may be located on the third stack layer IL3 in each of the plurality of trenches TRC. The second electrode CAT may include a transparent conductive material (TCO) such as ITO or IZO that can transmit light or a semi-transmissive conductive material such as magnesium (Mg), silver (Ag), or an alloy of Mg and Ag. When the second electrode CAT includes a semi-transmissive conductive material, the light emission efficiency may be relatively improved in each of the first to third sub-pixels SP1, SP2, and SP3 due to a micro-cavity effect.

The encapsulation layer TFE may be located on the display element layer EML. The encapsulation layer TFE may include at least one inorganic film TFE1 and TFE2 to reduce or prevent contaminants such as oxygen or moisture permeating into the display element layer EML. The first encapsulation inorganic film TFE1 may be located on the second electrode CAT, and the second encapsulation inorganic film TFE2 may be located on the first encapsulation inorganic film TFE1. The first encapsulation inorganic film TFE1 and the second encapsulation inorganic film TFE3 may be formed as multiple films in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In addition, the encapsulation layer TFE may include at least one organic film to protect the display element layer EML from foreign substances such as dust. The at least one organic film of the encapsulation layer TFE may be located between the first encapsulation inorganic film TFE1 and the second encapsulation inorganic film TFE2. The at least one organic film of the encapsulation layer TFE may be a monomer. Alternatively, at least one organic film of the encapsulation layer TFE may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be arranged on the adhesive layer ADL.

The first color filter CF1 may overlap the first emission area EA1 of the first sub-pixel SP1. The first color filter CF1 may transmit light of a first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of a second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of a third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be located on the plurality of lenses LNS. The filling layer FIL may have a selected refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate may be located on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but the embodiments of the present disclosure are not limited thereto. However, when visibility degradation caused by reflection of external light is sufficiently overcome by the first to third color filters CF1, CF2, and CF3, the polarizing plate may be omitted.

FIG. 8 is a cross-sectional view illustrating another example of a display panel taken along the line I1-I1′ of FIG. 5.

The embodiments of FIG. 8 differ from the embodiments of FIG. 7 in that the first electrode AND of each of the light emitting elements LE is in contact with and electrically connected to the side surface of a connection electrode ANC connected to the eighth conductive layer ML8. The embodiments of FIG. 8 also differ from the embodiments of FIG. 7 in that the trench TRC is omitted, and instead, the third pixel defining film PDL3 and a fourth pixel defining film PDL4 have an eaves-shaped or mushroom-shaped cross-sectional structure. In the embodiments of FIG. 8, some redundant description of parts already described in the embodiments of FIG. 7 may be omitted.

Referring to FIG. 8, the plurality of connection electrodes ANC may be respectively located on first portions AA1 of the ninth insulating film INS9. Each of the plurality of connection electrodes ANC may be located on the first portion AA1 of the ninth insulating film INS9 corresponding thereto. A plurality of connection electrodes ANC may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively located on the plurality of connection electrodes ANC. Each of the plurality of reflective electrodes RL may be located on the connection electrode ANC corresponding thereto. The plurality of reflective electrodes RL may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

A plurality of optical auxiliary films OAL may be respectively located on the plurality of reflective electrodes RL. Each of the plurality of optical auxiliary films OAL may be located on the reflective electrode RL corresponding thereto. The plurality of optical auxiliary films OAL may be formed as silicon oxide (SiOₓ)-based inorganic films, but the present disclosure is not limited thereto.

In each of the first emission area EA1 and the third emission area EA3, a step layer STPL may be located on the reflective electrode RL, and the optical auxiliary film OAL may be located on the step layer STPL. In the second emission area EA2, only the optical auxiliary film OAL may be located on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, the light emitting stack IL, and the second electrode CAT.

The first electrode AND of each of the light emitting elements LE may be located on the optical auxiliary film OAL corresponding thereto. Because the connection electrode ANC, the reflective electrode RL, and the optical auxiliary film OAL are sequentially stacked, the first electrode AND of each of the light emitting elements LE may be located on the top surface and the side surface of the optical auxiliary film OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby advantageously lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth insulating film INS9 may be substantially the same.

Alternatively, the thickness of the first portion AA1 of the ninth insulating film INS9 may be greater than the thickness of the second portion AA2 thereof. In this case, the side surface of the first portion AA1 of the ninth insulating film INS9 may be exposed, and the first electrode AND of each of the light emitting elements LE may be located on the exposed side surface of the first portion AA1 of the ninth insulating film INS9.

The first electrode AND of each of the light emitting elements LE may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light emitting elements LE may include titanium (Ti), titanium nitride (TiN), indium tin oxide (ITO), or indium zinc oxide (IZO), but the embodiments of the present disclosure are not limited thereto.

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be located on the first electrode AND of each of the light emitting elements LE. Specifically, the first pixel defining film PDL1 may cover a part of the top surface of the first electrode AND located on the optical auxiliary film OAL. Further, the first pixel defining film PDL1 may cover the first electrode AND located on the side surface of the connection electrode ANC, the side surface of the reflective electrode RL, and the side surface of the optical auxiliary film OAL. The first pixel defining film PDL1 may be located on the top surface of the second portion AA2 of the ninth insulating film INS9.

A planarization film PNS is a film for flattening the stepped portion caused by the connection electrode ANC, the reflective electrode RL, and the optical auxiliary film OAL.

The planarization film PNS may be located on the first pixel defining film PDL1 covering the first electrode AND located on the side surface of the connection electrode ANC, the side surface of the reflective electrode RL, and the side surface of the optical auxiliary film OAL. The planarization film PNS may be located on the first pixel defining film PDL1 located on the second portion AA2 of the ninth insulating film INS9.

The planarization film PNS may be located between the connection electrodes ANC adjacent in the first direction DR1 or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 located on the top surface of the first electrode AND located in the second emission area EA2.

In contrast, the top surface of the planarization film PNS may be flatly connected to the top surface of the first pixel defining film PDL1 located on the top surface of the first electrode AND located in the first emission area EA1 and the third emission area EA3. That is, the planarization film PNS may not cover the top surface of the first pixel defining film PDL1 located on the top surface of the first electrode AND located in each of the first emission area EA1 and the third emission area EA3.

The second pixel defining film PDL2 may be located on the first pixel defining film PDL1 and the planarization film PNS, the third pixel defining film PDL3 may be located on the second pixel defining film PDL2, and the fourth pixel defining film PDL4 may be located on the third pixel defining film PDL3. The first pixel defining film PDL1 and the third pixel defining film PDL3 may be formed as silicon nitride (SiNₓ)-based inorganic films, whereas the second pixel defining film PDL2, the fourth pixel defining film PDL4, and the planarization film PNS may be formed as silicon oxide (SiOₓ)-based inorganic films. The first pixel defining film PDL1 includes a material different from that of the planarization film PNS, and thus may serve as a stopper in a chemical mechanical polishing process for the planarization film PNS.

When the planarization film PNS and the second pixel defining film PDL2 are both formed as silicon oxide (SiOₓ)-based inorganic films, the planarization film PNS and the second pixel defining film PDL2 may be formed as a single film.

Because the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. In other words, the third pixel defining film PDL3 and the fourth pixel defining film PDL4 may have an eave-shaped or mushroom-shaped cross-sectional structure.

The light emitting stack IL may be located on the first electrode AND the pixel defining film PDL. The light emitting stack IL may include the first stack layer IL1 and the second stack layer IL2 that emit different lights. When the light emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be located between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer located between the first stack layer IL1 and the second stack layer IL2 may also be cut off. Further, although FIG. 8 illustrates that the second stack layer IL2 is connected without being cut off, the second hole transport layer of the second stack layer IL2 may be cut off, and the second electron transport layer of the second stack layer IL2 may be connected without being cut off. Therefore, it may be possible to prevent or reduce a leakage current flowing through the first hole transport layer of the first stack layer IL1, the second hole transport layer of the second stack layer IL2, and the charge generation layer CGL between the adjacent emission areas EA1, EA2, and EA3. Accordingly, it may be possible to prevent or reduce the light emitting stack IL in the adjacent emission areas EA1, EA2, and EA3 emitting light other than the originally intended light due to the influence of the above current.

Although FIG. 8 illustrates a two-tandem structure in which the light emitting stack IL includes two stack layers IL1 and IL2, the present disclosure is not limited thereto. For example, the light emitting stack IL may have a three-tandem structure including three stack layers as shown in FIG. 7. In this case, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as shown in FIG. 7, the trench TRC penetrating the first pixel defining film PDL1, the second pixel defining film PDL2, and the third pixel defining film PDL3 may be added. In this case, the trench TRC may penetrate at least a part of the ninth insulating film INS9, but the present disclosure is not limited thereto.

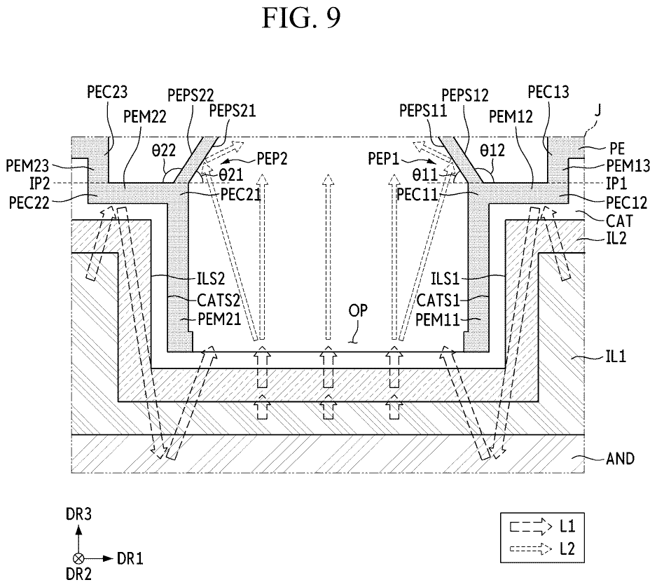

FIG. 9 is a cross-sectional view showing a display device according to some embodiments of the present disclosure. FIG. 9 is also a partially enlarged view showing part J of FIG. 8.

Referring to FIG. 9, a display device according to some embodiments of the present disclosure includes the first electrode AND, light emitting stacks IL1 and IL2 located on the first electrode AND, the second electrode CAT located on the light emitting stacks IL1 and IL2, and a third electrode PE located on the second electrode CAT.

In cross-sectional view, the third electrode PE may include a first main portion PEM1, a first protrusion PEP1 protruding from the first main portion PEM1, a second main portion PEM2, a second protrusion PEP2 protruding from the second main portion PEM2, and an opening OP. Depending on a portion of the display panel to be viewed in cross-sectional view, the third electrode PE may include only the first main portion PEM1, and the first protrusion PEP1 protruding from the first main portion PEM1 in cross-sectional view. This will be described later.

The first main portion PEM1 may include an eleventh main portion PEM11, a twelfth main portion PEM12, a thirteenth main portion PEM13, an eleventh bent portion PEC11 that connects the eleventh main portion PEM11 and the twelfth main portion PEM12 to each other, and a twelfth bent portion PEC12 that connects the twelfth main portion PEM12 and the thirteenth main portion PEM13 to each other. The eleventh bent portion PEC11 may be formed at one end of the eleventh main portion PEM11, and another bent portion may be formed at the other end of the eleventh main portion PEM11. Another bent portion may be provided at the first main portion PEM1 to form one side of the opening OP.

The light emitting stacks IL1 and IL2 may include a side surface portion ILS1 formed by a pixel defining film and/or a planarization film. The second electrode CAT may include a side surface portion CATS1 formed by a pixel defining film and/or a planarization film. Due to the thickness of the second electrode CAT and the light emitting stacks IL1 and IL2 formed on the first electrode AND, the side surface portion ILS1 of the light emitting stacks IL1 and IL2 and the side surface portion CATS1 of the second electrode CAT may be formed to overlap at least partially.

According to some embodiments, the side surface portion CATS1 of the second electrode CAT may be located between the eleventh main portion PEM11 and the side surface portion ILS1 of the light emitting stacks IL1 and IL2. The eleventh main portion PEM11 may be arranged to extend in the third direction DR3. The eleventh bent portion PEC11 may be connected to one end of the eleventh main portion PEM11 and one end of the twelfth main portion PEM12. The eleventh bent portion PEC11 may be located between the eleventh main portion PEM11 and the twelfth main portion PEM12. The twelfth main portion PEM12 may be arranged to extend in the first direction DR1. The first main portion PEM1 may be extended in the third direction DR3 and then extended in the first direction DR1 by the eleventh bent portion PEC11. The other end of the twelfth main portion PEM12 may be connected to the twelfth bent portion PEC12. The twelfth bent portion PEC12 may be located between the twelfth main portion PEM12 and the thirteenth main portion PEM13. The first main portion PEM1 may be extended in the first direction DR1 and then extended again in the third direction DR3 by the twelfth bent portion PEC12.

The first protrusion PEP1 may protrude from the first main portion PEM1. The first protrusion PEP1 may protrude from the eleventh bent portion PEC11. The first protrusion PEP1 may protrude from the twelfth main portion PEM12.

The first protrusion PEP1 may extend in the upward direction of the display device. At this time, a first side surface PEPS11 of the first protrusion PEP1 may form a selected angle θ11 with the twelfth main portion PEM12. A second side surface PEPS12 of the first protrusion PEP1 may form a selected angle θ12 with the twelfth main portion PEM12. An imaginary first plane IP1 including the twelfth main portion PEM12 and the first side surface PEPS11 of the first protrusion PEP1 may form the eleventh angle θ11. The imaginary first plane IP1 including the twelfth main portion PEM12 and the second side surface PEPS12 of the first protrusion PEP1 may form the twelfth angle θ12. According to some embodiments, the eleventh angle θ11 may be an acute angle. The eleventh angle θ11 may be less than a right angle. The twelfth angle θ12 may be an obtuse angle. The twelfth angle θ12 may be greater than a right angle. By forming the eleventh angle θ11 as an acute angle and the twelfth angle θ12 as an obtuse angle, the first protrusion PEP1 may be arranged to extend toward the center of the opening OP.

The light emitting stacks IL1 and IL2 may include a side surface portion ILS2 formed by a pixel defining film and/or a planarization film. The second electrode CAT may include a side surface portion CATS2 formed by a pixel defining film and/or a planarization film. Due to the thickness of the second electrode CAT and the light emitting stacks IL1 and IL2 formed on the first electrode AND, the side surface portion ILS2 of the light emitting stacks IL1 and IL2 and the side surface portion CATS2 of the second electrode CAT may be formed to overlap at least partially.

According to some embodiments, the side surface portion CATS2 of the second electrode CAT may be located between a twenty-first main portion PEM21 and the side surface portion ILS2 of the light emitting stacks IL1 and IL2. The twenty-first main portion PEM21 may be arranged to extend in the third direction DR3. A twenty-first bent portion PEC21 may be connected to one end of the twenty-first main portion PEM21 and one end of a twenty-second main portion PEM22. The twenty-first bent portion PEC21 may be located between the twenty-first main portion PEM21 and the twenty-second main portion PEM22. The twenty-second main portion PEM22 may be arranged to extend in the second direction DR2. The second main portion PEM2 may be extended in the third direction DR3 and then extended in the second direction DR2 by the twenty-first bent portion PEC21. The other end of the twenty-second main portion PEM22 may be connected to the twenty-second bent portion PEC22. The twenty-second bent portion PEC22 may be located between the twenty-second main portion PEM22 and a twenty-third main portion PEM23. The second main portion PEM2 may be extended in the second direction DR2 and then extended again in the third direction DR3 by the twenty-second bent portion PEC22.

The second protrusion PEP2 may protrude from the second main portion PEM2. The second protrusion PEP2 may protrude from the twenty-first bent portion PEC21. The second protrusion PEP2 may protrude from the twenty-second main portion PEM22.

The second protrusion PEP2 may extend in the upward direction of the display device. At this time, a first side surface PEPS21 of the second protrusion PEP2 may form a selected angle θ21 with the twenty-second main portion PEM22. A second side surface PEPS22 of the second protrusion PEP2 may form a selected angle θ22 with the twenty-second main portion PEM22. An imaginary second plane IP2 including the twenty-second main portion PEM22 and the first side surface PEPS21 of the second protrusion PEP2 may form the twenty-first angle θ21. The imaginary second plane IP2 including the twenty-second main portion PEM22 and the second side surface PEPS22 of the second protrusion PEP2 may form the twenty-second angle θ22. According to some embodiments, the twenty-first angle θ21 may be an acute angle. The twenty-first angle θ21 may be less than a right angle. The twenty-second angle θ22 may be an obtuse angle. The twenty-second angle θ22 may be greater than a right angle. By forming the twenty-first angle θ21 as an acute angle and forming the twenty-second angle θ22 as an obtuse angle, the second protrusion PEP2 may be arranged to extend toward the center of the opening OP.

In the display device according to some embodiments of the present disclosure, the third electrode PE may include the opening OP. Electrons supplied from the second electrode CAT may be combined with holes supplied from the first electrode AND to form excitons in the light emitting stacks IL1 and IL2. The light emitting stacks IL1 and IL2 may emit light.

The emitted light may be divided into first light L1 that has not passed through the opening OP and second light L2 that has passed through the opening OP. The light emitted from the region that overlaps the opening OP among the first light L1 may be directed to the upper side of the display device without being affected by another reflection or the like. In order to direct the light emitted from the region that does not overlap the opening OP among the first light L1 toward the opening OP, according to some embodiments, the reflectivity of the third electrode PE may be higher than the reflectivity of the second electrode CAT. Further, the transmittance of the second electrode CAT may be higher than the transmittance of the third electrode PE.

At least a part of the light emitted from the region that does not overlap the opening OP may pass through the second electrode CAT, and the other light may be reflected by the second electrode CAT. The light reflected from the second electrode CAT may be directed to the reflective electrode located under the second electrode CAT for the above-described micro cavity effect or the like.

In order to send the light that has passed through the second electrode CAT among the light emitted from the region that does not overlap the opening OP to an operator's intended location, the reflectivity of the third electrode PE may be formed to be higher than the reflectivity of the second electrode CAT. In this case, the light that has passed through the second electrode CAT may be reflected by the third electrode PE and collected at the center of the sub-pixel.

The emitted light may be divided into the first light L1 that has not passed through the opening OP and the second light L2 that has passed through the opening OP. The second light L2 may be divided into light reflected by the first protrusion PEP1 or the second protrusion PEP2 and light that is not reflected. Among the second light L2, the light that is not reflected by the first protrusion PEP1 or the second protrusion PEP2 may be directed toward the center of the sub-pixel. Among the second light L2, the light that is reflected may be directed toward the first protrusion PEP1 and/or the second protrusion PEP2. The inclination of the first protrusion PEP1 toward the center of the sub-pixel may be determined by the eleventh angle θ11 and the twelfth angle θ12. The inclination of the second protrusion PEP2 toward the center of the sub-pixel may be determined by the twenty-first angle θ21 and the twenty-second angle θ22. The first protrusion PEP1 and the second protrusion PEP2 may protrude from the first main portion PEM1 and the second main portion PEM2 of the third electrode PE, respectively. Therefore, the reflectivity of the first protrusion PEP1 and the second protrusion PEP2 may be higher than that of the second electrode CAT. Alternatively, the transmittance of the first protrusion PEP1 and the second protrusion PEP2 may be lower than that of the second electrode CAT. According to some embodiments, the light reflected by the first protrusion PEP1 and the second protrusion PEP2 that perform the reflection function may be collected at the center of the sub-pixel.

In the display device according to some embodiments of the present disclosure, a plurality of display devices having a high resolution and a high integration may be included. In order to use the plurality of display devices, the light emitted from the display panel included in the display device may be directed toward the center of the display panel. A lens (or micro lens) may be located on the color filter of the display device to perform a light collecting function. When the lens is located on the color filter to perform a light collecting function, the emitted light passes through an encapsulation film or the like, thereby deteriorating the luminance in user's both eyes. Further, the thickness of the entire display device may increase due to the arrangement of the lens.

According to some embodiments, the lens is removed and the third electrode PE is located to perform the light collecting function, preventing an increase in the thickness of the display device, and reducing the deterioration in the luminance of the display device. The third electrode PE may be located on the second electrode CAT. The third electrode PE may be located between the second electrode CAT and the first encapsulation inorganic film. Alternatively, the third electrode PE may be located between the first encapsulation inorganic film and the encapsulation organic film. Alternatively, the third electrode PE may be located between the encapsulation organic film and the second encapsulation inorganic film. Alternatively, the third electrode PE may be located on the second encapsulation inorganic film.

In order to control the direction of the emitted light by using the third electrode PE placed instead of the lens, the third electrode PE may include a single or multiple protrusions. As will be described below, the concept of a single or multiple protrusions is confirmed in cross-sectional view, and the protrusion may be connected as one in plan view or the like.

Because the protrusion of the third electrode PE perform a reflective function relatively more than the second electrode CAT, if the main portion including the protrusion is entirely formed on the second electrode CAT, a problem that light emitted from the light emitting stacks IL1 and IL2 does not pass through the third electrode PE may occur. Accordingly, according to some embodiments, the opening OP is separately formed in the third electrode PE to easily control the light direction and solve the problem of securing luminance.

Further, according to some embodiments, the light direction controlled by the protrusion may be different for each region of the display device.

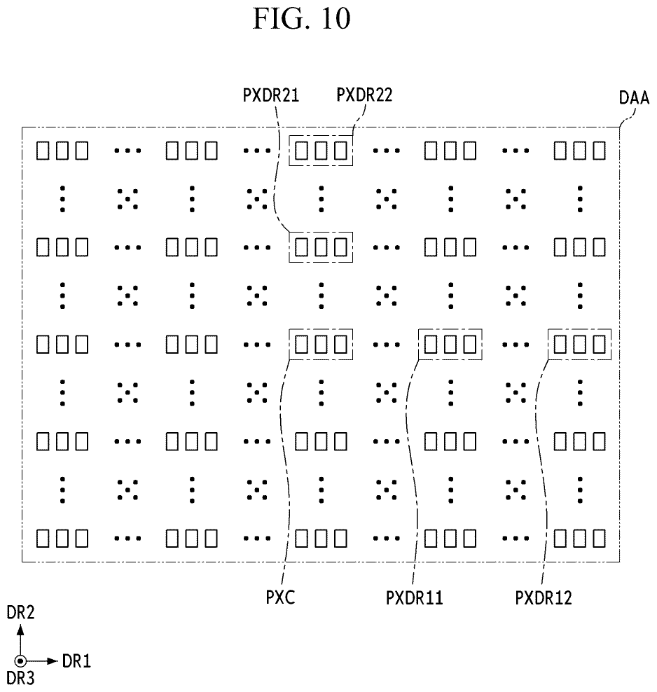

FIG. 10 is a cross-sectional view showing a display panel according to some embodiments of the present disclosure.

Referring to FIG. 10, the display area DAA according to some embodiments may be divided into a first region corresponding to the first portion, a second region corresponding to the second portion, and a third region corresponding to the third portion. For example, the second portion may be closer to the first portion than the third portion. In the display device according to some embodiments, the first portion as a reference is set and the other parts are classified according to the degree of proximity to the first portion and, then, the directions of lights emitted from sub-pixels located in the respective portions may be formed to be different from each other.

According to some embodiments, the display area DAA may include a center pixel PXC, a first pixel PXDR11, and a second pixel PXDR12. The center pixel PXC may be a pixel located at the center of the display device. Both the first pixel PXDR11 and the second pixel PXDR12 may be pixels arranged in the first direction DR1 from the center pixel PXC. The first pixel PXDR11 may be closer to the center pixel PXC than the second pixel PXDR12.

According to some embodiments, the display area DAA may include the center pixel PXC, a third pixel PXDR21, and a fourth pixel PXDR22. The center pixel PXC may be a pixel located at the center of the display area DAA. Both the third pixel PXDR21 and the fourth pixel PXDR22 may be pixels arranged in the second direction DR2 from the center pixel PXC. The third pixel PXDR21 may be closer to the center pixel PXC than the fourth pixel PXDR22.

According to some embodiments, the center pixel PXC may correspond to the first portion described above. However, the embodiments of the present disclosure are not limited thereto. The first portion may be a portion where light is directed macroscopically in the display device. The first portion may not be limited to the center pixel PXC. The first portion may be set as any portion of the display area DAA, and when the first portion is determined, the second portion and the third portion may also be determined. The second portion may be closer to the first portion than the third portion.

On the assumption that the center pixel PXC corresponds to the first portion, the first pixel PXDR11 may correspond to the second portion described above. Further, the second pixel PXDR12 may correspond to the third portion described above.

According to some embodiments, on the assumption that the center pixel PXC corresponds to the first portion, the third pixel PXDR21 may correspond to the second portion described above. Further, the fourth pixel PXDR22 may correspond to the third portion described above.

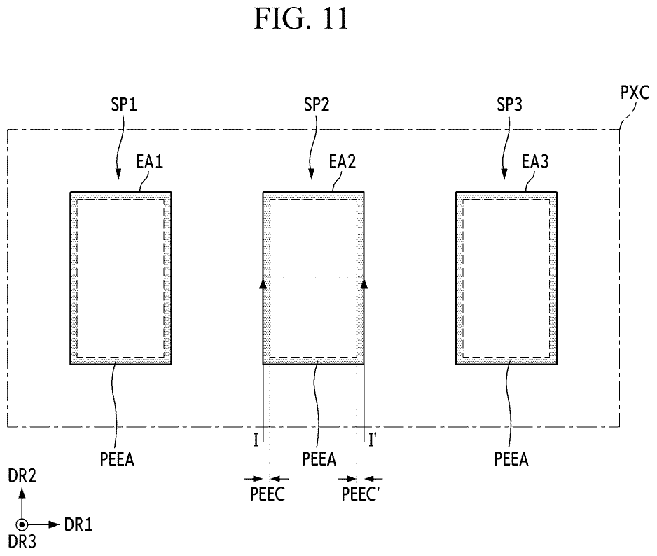

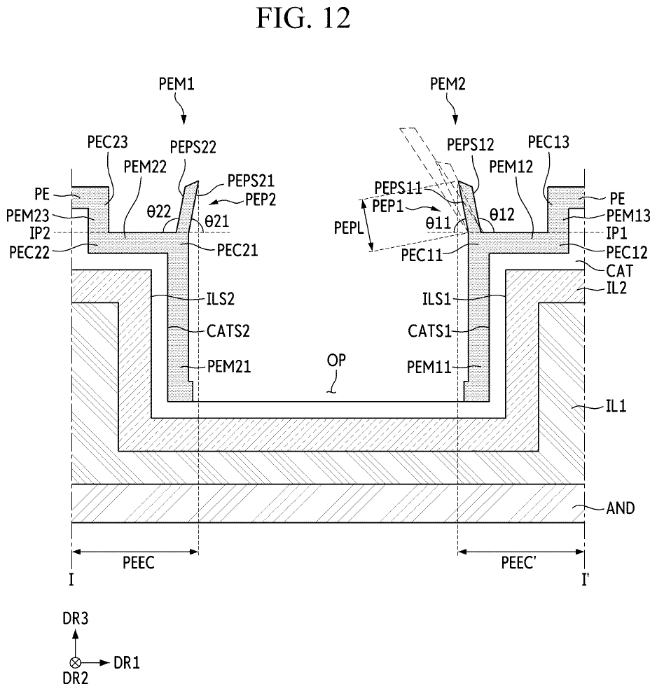

FIG. 11 is a cross-sectional view showing a display panel according to some embodiments of the present disclosure. FIG. 12 is a cross-sectional view taken along the line I-I′ of FIG. 11.

Referring to FIGS. 11 and 12, the center pixel PXC may include the first sub-pixel SP1, the second sub-pixel SP2, and the third sub-pixel SP3 respectively having the first emission area EA1, the second emission area EA2, and the third emission area EA3.

For example, in the center pixel PXC, the second sub-pixel SP2 may include a protrusion that is connected as one. For example, the first protrusion PEP1 and the second protrusion PEP2 may appear to be separated in cross-sectional view, but may be connected as one in plan view. A region PEEA defined as a portion covered by the third electrode PE may include a plurality of lengths PEEC and PEEC′ in the first direction DR1. When the center pixel PXC corresponds to the first portion, the plurality of lengths PEEC and PEEC′ in the first direction DR1 may be identical to each other.

The plurality of lengths PEEC and PEEC′ in the first direction DR1 may include the length PEEC from one edge of the second emission area EA2 to the end of the second protrusion PEP2 and the length PEEC′ from the other edge of the second emission area EA2 to the end of the first protrusion PEP1. When they are equal to each other, the eleventh angle θ11 may be substantially equal to the twenty-first angle θ21. Alternatively, the twelfth angle θ12 may be substantially equal to the twenty-second angle θ22. The inclination of the first protrusion PEP1 and the inclination of the second protrusion PEP2 may also be substantially equal to each other. According to some embodiments, a length PEPL of the first protrusion PEP1 and the length of the second protrusion PEP2 may be equal to each other.

As illustrated, the end of the first protrusion PEP1 may be relatively closer to the center of the sub-pixel than one end of the opening OP. Further, the end of the second protrusion PEP2 may be relatively closer to the center of the sub-pixel than the other end of the opening OP. However, the embodiments of the present disclosure are not limited thereto. When the length PEPL of the first protrusion PEP1 and the length of the second protrusion PEP2 are formed to be shorter, one end and the other end of the opening OP may be relatively closer than the end of the first protrusion PEP1 and the end of the second protrusion PEP2.

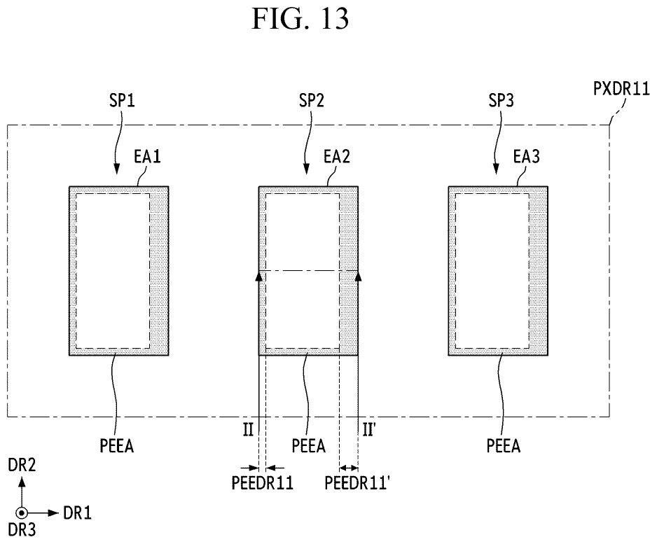

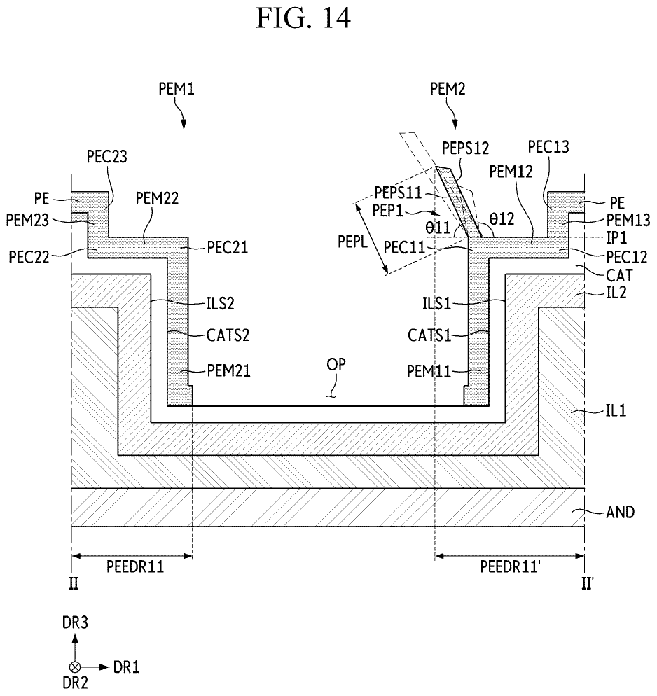

FIG. 13 is a plan view showing a display panel according to some embodiments of the present disclosure. FIG. 14 is a cross-sectional view taken along the line II-II′ of FIG. 13.

Referring to FIGS. 13 and 14, the first pixel PXDR11 may include the first sub-pixel SP1, the second sub-pixel SP2, and the third sub-pixel SP3 respectively having the first emission area EA1, the second emission area EA2, and the third emission area EA3.

For example, in the first pixel PXDR11, the second sub-pixel SP2 may include a protrusion that is connected as one. In cross-sectional view, the second main portion PEM2 may not include a protrusion. The first pixel PXDR11 may include the single first protrusion PEP1 in cross-sectional view. According to some embodiments, in the second main portion PEM2 adjacent to the center pixel PXC, the length PEPL of the protrusion may decrease from the center pixel PXC toward the first pixel PXDR11. Alternatively, the second main portion PEM2 may not include a protrusion.

The region PEEA defined as a portion covered by the third electrode PE may include a plurality of eleventh direction lengths PEEDR11 and PEEDR11′. When the center pixel PXC corresponds to the first portion, the plurality of eleventh direction lengths PEEDR11 and PEEDR11′ may be different from each other.

The plurality of eleventh direction lengths PEEDR11 and PEEDR11′ may include the length PEEDR11 from one edge of the second emission area EA2 to one end of the opening OP and the length PEEDR11′ from the other edge of the second emission area EA2 to the end of the first protrusion PEP1. The length PEEDR11′ from the other edge of the second emission area EA2 to the end of the first protrusion PEP1 may be greater than the length PEEDR11 from one edge of the second emission area EA2 to one end of the opening OP.

According to some embodiments, the inclination and length PEPL of the protrusion provided in the first pixel PXDR11 may be different from the inclination and length PEPL of the protrusion provided in the center pixel PXC. As described above, the light direction and the degree of light collection may be adjusted by changing the inclination and length of the protrusion from the first portion toward the second portion and the third portion.

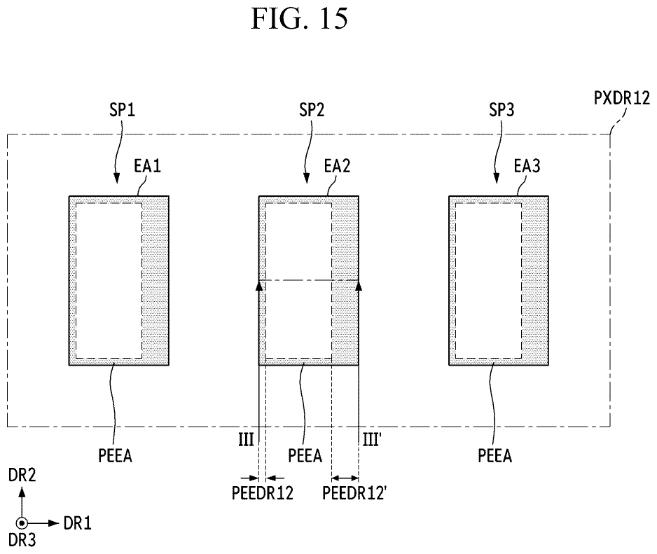

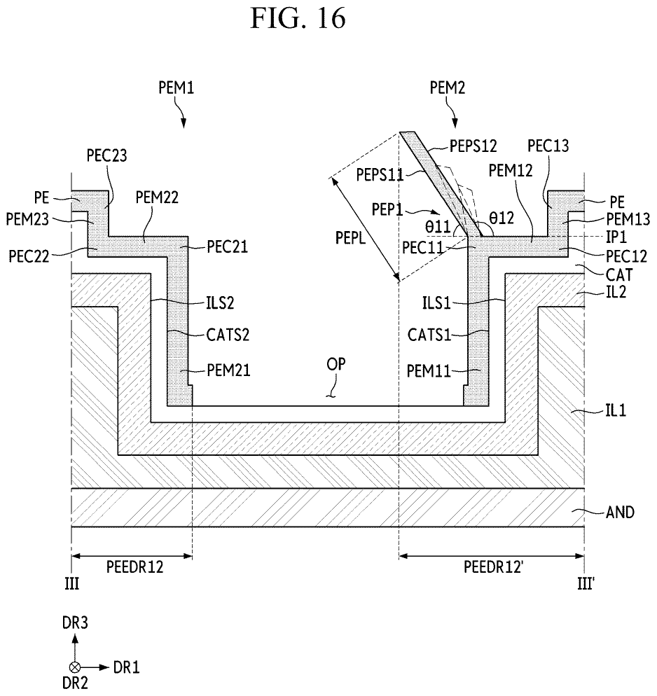

FIG. 15 is a plan view showing a display panel according to some embodiments of the present disclosure. FIG. 16 is a cross-sectional view taken along the line III-III′ of FIG. 15.

Referring to FIGS. 15 and 16, the second pixel PXDR12 may include the first sub-pixel SP1, the second sub-pixel SP2, and the third sub-pixel SP3 respectively having the first emission area EA1, the second emission area EA2, and the third emission area EA3.

For example, in the second pixel PXDR12, the second sub-pixel SP2 may include a protrusion that is connected as one. In cross-sectional view, the second main portion PEM2 may not include a protrusion. The second pixel PXDR12 may include the single first protrusion PEP1 in cross-sectional view. According to some embodiments, in the second main portion PEM2 adjacent to the center pixel PXC, the length PEPL of the protrusion may decrease from the center pixel PXC toward the second pixel PXDR12. Alternatively, the second main portion PEM2 may not include a protrusion.

The region PEEA defined as a portion covered by the third electrode PE may include a plurality of twelfth direction lengths PEEDR12 and PEEDR12′. When the center pixel PXC corresponds to the first portion, the plurality of twelfth direction lengths PEEDR12 and PEEDR12′ may be different from each other.

The plurality of twelfth direction lengths PEEDR12 and PEEDR12′ may include the length PEEDR12 from one edge of the second emission area EA2 to one end of the opening OP and the length PEEDR12′ from the other edge of the second emission area EA2 to the end of the first protrusion PEP1. The length PEEDR12′ from the other edge of the second emission area EA2 to the end of the first protrusion PEP1 may be greater than the length PEEDR12 from one edge of the second emission area EA2 to one end of the opening OP.

According to some embodiments, the inclination and length PEPL of the protrusion provided in the second pixel PXDR12 may be different from the inclination and length PEPL of the protrusion provided in the center pixel PXC. As described above, the light direction and the degree of light collection may be adjusted by changing the inclination and length of the protrusion from the first portion toward the second portion and the third portion.

Referring to FIGS. 12, 14, and 16, in order to collect light at the center pixel PXC, the eleventh angle θ11 at the center pixel PXC may be greater than the eleventh angle θ11 at the first pixel PXDR11 and the eleventh angle θ11 at the second pixel PXDR12. Further, the eleventh angle θ11 at the first pixel PXDR11 closer to the center pixel PXC may be greater than the eleventh angle θ11 at the second pixel PXDR12.

On the contrary, in order to collect light at the center pixel PXC, the twelfth angle θ12 at the center pixel PXC may be less than the twelfth angle θ12 at the first pixel PXDR11 and the twelfth angle θ12 at the second pixel PXDR12. Further, the twelfth angle θ12 at the first pixel PXDR11 closer to the center pixel PXC may be less than the twelfth angle θ12 at the second pixel PXDR12. An appropriate value according to the chief ray angle (CRA) may be applied as the inclination of the protrusions.

Further, the length PEPL of the protrusion may also be adjusted in order to collect light at the center pixel PXC. For example, in order to collect light at the center pixel PXC, the protrusion length PEPL at the center pixel PXC may be less than the protrusion length PEPL at the first pixel PXDR11 and the protrusion length PEPL at the second pixel PXDR12. Further, the protrusion length PEPL at the first pixel PXDR11 closer to the center pixel PXC may be less than the protrusion length PEPL at the second pixel PXDR12.

Further, by combining the inclination and length of the protrusions, the area of the region where the first protrusion overlaps the second electrode (or, the opening) in the plane direction of the display area may also be adjusted. For example, as the distance from the center pixel PXC increases, the length PEPL of the protrusion increases, and the eleventh angle θ11 decreases, so that the area of the region where the protrusion overlaps the second electrode (or, the opening) in the plane direction (or the orthogonal projection area to the display area) of the display area may tend to further increase in a pixel distant from the center pixel PXC.

In the display device according to some embodiments of the present disclosure, the inclination and length PEPL of the protrusion may be formed to be different for each region provided in the display area. Accordingly, the light direction and the degree of light collection may be adjusted instead of the function of the lens, and the decrease in the luminance of the display device may be prevented or reduced.

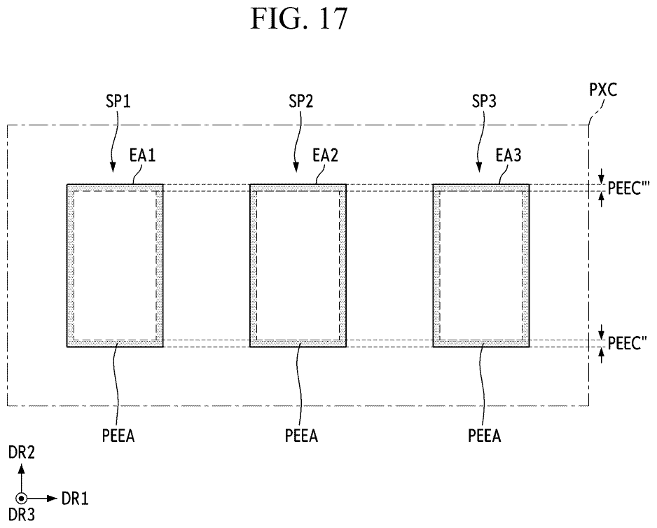

FIGS. 17 to 19 are plan views showing a display panel according to some embodiments of the present disclosure.

Referring to FIG. 17, the plurality of lengths in the second direction DR2 in the center pixel PXC may include a length PEEC″ from one edge of the second emission area EA2 to the end of the third electrode and a length PEEC′″ from the other edge of the second emission area EA2 to the end of the third electrode.

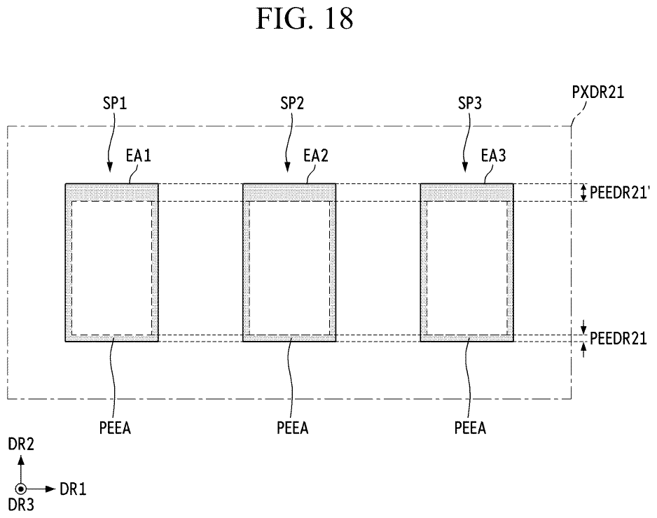

Referring to FIG. 18, the plurality of lengths in the second direction DR2 in the third pixel PXDR21 may include a length PEEDR21 from one edge of the second emission area EA2 to the end of the third electrode and a length PEEDR21′ from the other edge of the second emission area EA2 to the end of the third electrode.

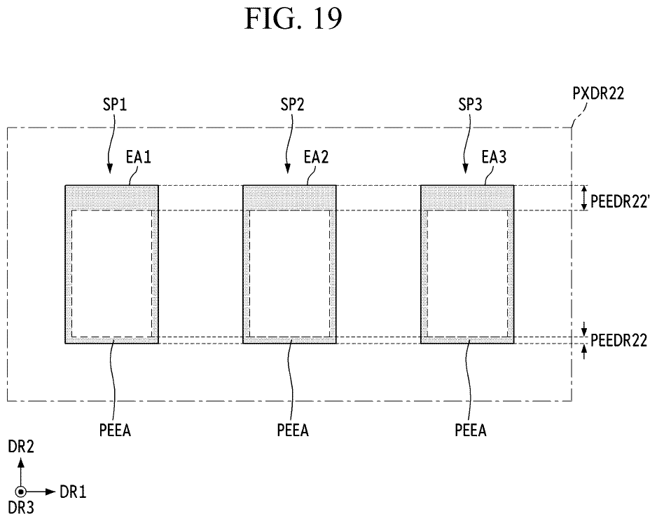

Referring to FIG. 19, the plurality of lengths in the second direction DR2 in the fourth pixel PXDR22 may include a length PEEDR22 from one edge of the second emission area EA2 to the end of the third electrode and a length PEEDR22′ from the other edge of the second emission area EA2 to the end of the third electrode.

Referring to FIGS. 17 to 19, the length PEEC′″ from the other edge of the second emission area EA2 to the end of the third electrode may be less than the length PEEDR21′ from the other edge of the second emission area EA2 to the end of the third electrode and the length PEEDR22′ from the other edge of the second emission area EA2 to the end of the third electrode. Further, the length PEEDR21′ from the other edge of the second emission area EA2 to the end of the third electrode may be less than the length PEEDR22′ from the other edge of the second emission area EA2 to the end of the third electrode.

In the illustrated embodiments, the length from the edge of the emission area to the end of the third electrode is compared only in the first direction DR1 or only in the second direction DR2. However, the embodiments of the present disclosure are not limited thereto, and embodiments in which the length changes in both the first direction DR1 and the second direction DR2 may also be derived with reference to the present disclosure.

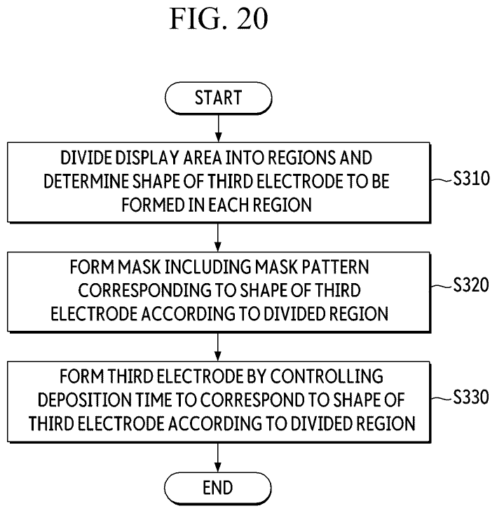

FIG. 20 is a flowchart showing aspects of a method of manufacturing a display panel according to some embodiments of the present disclosure. Although FIG. 20 illustrates various operations in a method of manufacturing a display panel according to some embodiments, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

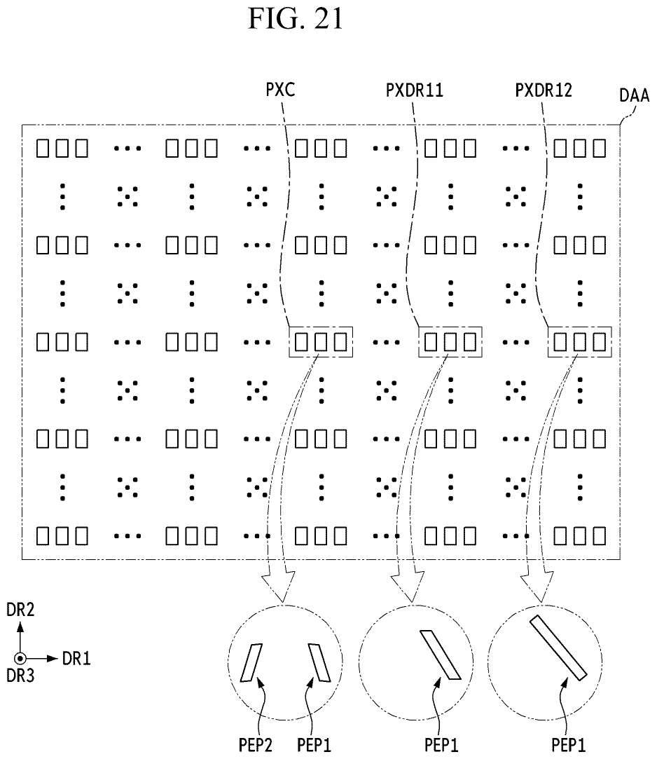

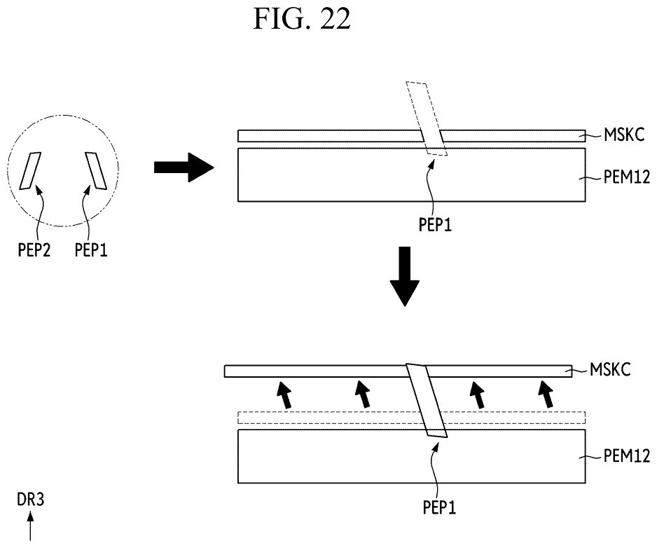

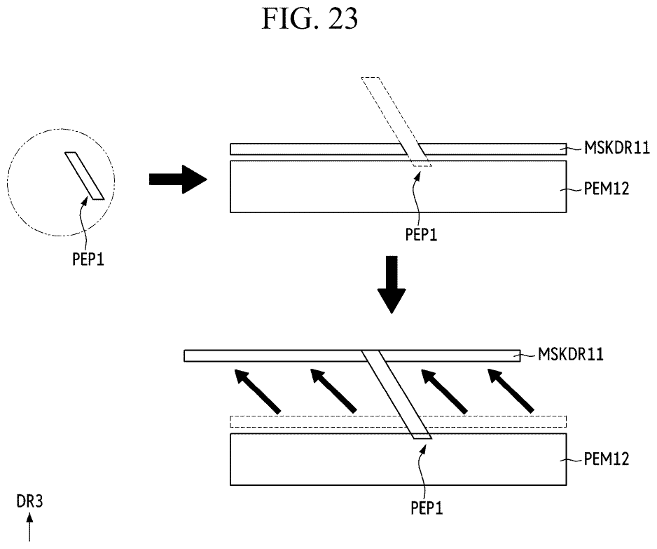

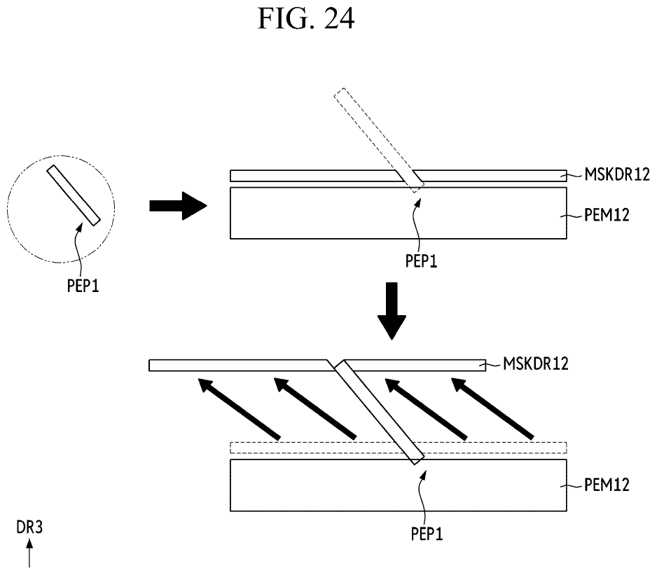

FIGS. 21 to 24 are cross-sectional views illustrating further details of a method of manufacturing a display panel according to some embodiments of the present disclosure.

Referring to FIGS. 20 and 21, each display area DAA may be divided into the first region corresponding to the first portion, the second region corresponding to the second portion, and the shape of the third electrode PE to be formed in each region may be determined (see operation S310). In the center pixel PXC, the third electrode PE including the first protrusion PEP1 and the second protrusion PEP2 that are formed at substantially the same inclination may be formed. In the first pixel PXDR11, the third electrode PE including the first protrusion PEP1 having the eleventh angle θ11 less than the eleventh angle θ11 of the center pixel PXC may be formed. In the second pixel PXDR12, the third electrode PE including the first protrusion PEP1 having the eleventh angle θ11 less than the eleventh angle θ11 of the first pixel PXDR11 may be formed. Additionally, their lengths may also be determined.

Referring to FIGS. 20 and 22 to 24, a mask pattern may be determined by considering the inclination of the protrusion corresponding to each region. Further, a mask including the mask pattern may be manufactured (see operation S320).

Accordingly, a mask for forming the center pixel PXC, a mask for forming the first pixel PXDR11, and a mask for forming the second pixel PXDR12 may be manufactured.

Referring to FIGS. 20 and 22 to 24, the third electrode PE may be deposited using a mask corresponding to each region (see operation S330). If the protrusion inclination is considered in the mask pattern, the protrusion lengths may be formed to be different from each other by controlling the deposition time using the mask. For example, in the protrusion of the second pixel PXDR12 having a relatively longer length, the deposition time of the third electrode PE may be longer than those in the others such as the center pixel PXC and the like.

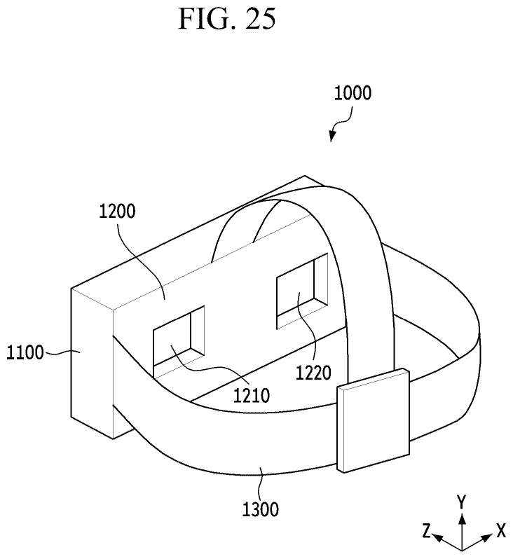

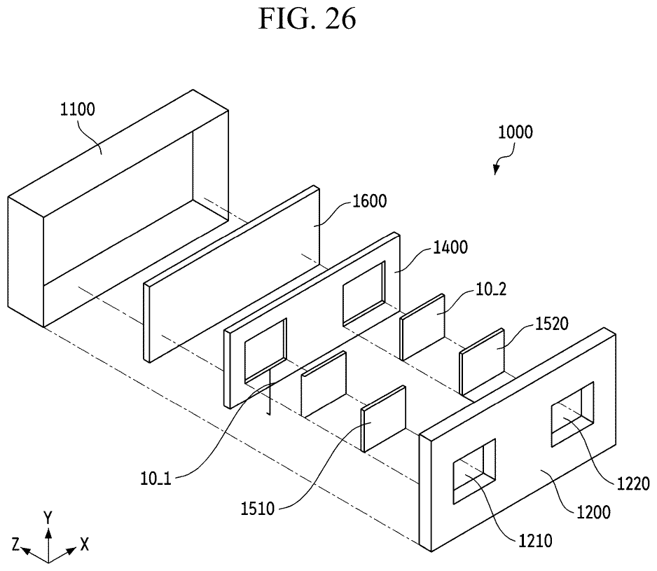

FIG. 25 is a perspective view illustrating a head mounted display according to some embodiments of the present disclosure. FIG. 26 is an exploded perspective view illustrating an example of the head mounted display of FIG. 25.

Referring to FIGS. 25 and 26, a head mounted display 1000 according to some embodiments of the present disclosure includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 to 8, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 25 and 26 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

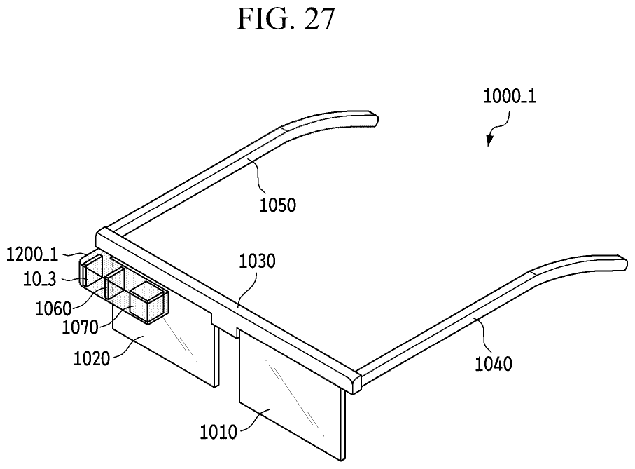

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 27, an eyeglass frame instead of the head mounted band 1300.

FIG. 27 is a perspective view illustrating a head mounted display according to some embodiments of the present disclosure.

Referring to FIG. 27, a head mounted display 1000_1 according to some embodiments may be an eyeglasses-type display device in which a display device housing 1200_1 is implemented in a lightweight and compact manner. The head mounted display 1000_1 according to some embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 27 illustrates that the display device housing 1200_1 is located at the right end of the support frame 1030, but the embodiments of the present specification are not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

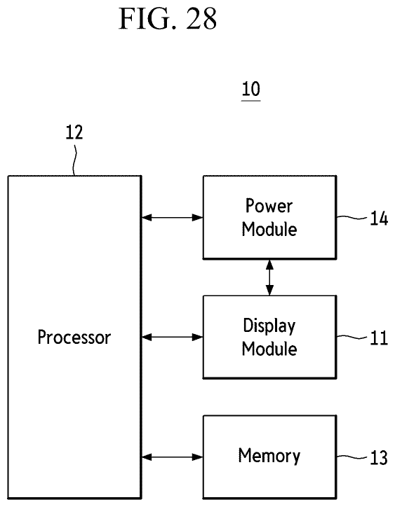

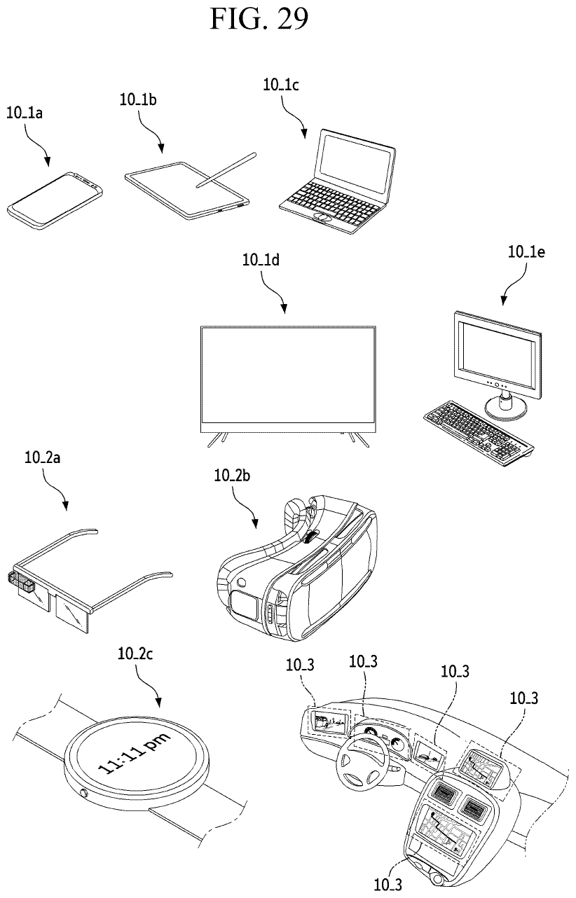

FIG. 28 is a block diagram of an electronic device according to some embodiments of the present disclosure. FIG. 29 is schematic diagrams of electronic devices according to various embodiments of the present disclosure.

Referring to FIG. 28, an electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information required for the operation of the processor 12 or display module 11 may be stored in the memory 15. When the processor 12 executes an application stored in the memory 15, an image data signal and/or an input control signal may be transmitted to the display module 11, and the display module 11 may process the provided signal and may output image information through a display screen.

The power module 14 may include a power supply module such as a power adapter or a battery device. The power module 14 may include a power conversion module. The power conversion module may convert the power supplied by the power supply module to generate a power required for the operation of the electronic device 10.

At least one of each of the components of the above-described electronic device 10 may be included in the display device according to the embodiments described above. In addition, some of the individual modules that are functionally included in a single module may be included in the display device, whereas some others thereof may be provided separately from the display device. For example, the display device may include the display module 11, whereas the processor 12, the memory 13 and the power module 14 may be provided in the form of other devices in the electronic device, other than the display device.

Referring to FIG. 29, various electronic devices to which display devices according to embodiments of the present disclosure are applied may include an electronic device for displaying images, such as a smartphone 10_1a, a tablet PC 10_1b, a laptop 10_1c, a TV 10_1d, and a desk monitor 10_1e. In addition, various electronic devices to which the display devices according to the embodiments of the present disclosure are applied may include a wearable electronic device including a display module such as smart glasses 10_2a, a head mounted display 10_2b, and a smart watch 10_2c, a vehicle electronic device 10_3 including a display module such as a room mirror display, a center information display (CID) placed on a dashboard, a center fascia, and an instrument panel of a car, and the like.

Although aspects of some embodiments of the present disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are examples in all respects and are not intended to be limiting.

What is claimed is:

1. A display device comprising:
a substrate on which a display area is defined;
a reflective electrode on the substrate;
an optical auxiliary layer on the reflective electrode;
a first electrode on the optical auxiliary layer;
a light emitting stack on the first electrode;
a second electrode on the light emitting stack; and
a third electrode on the second electrode,
wherein the third electrode comprises:
a first main portion on the second electrode; and
a first protrusion protruding from the first main portion.

2. The display device of claim 1, wherein the first main portion comprises an eleventh main portion, a twelfth main portion, and an eleventh bent portion between the eleventh main portion and the twelfth main portion and connecting the eleventh main portion and the twelfth main portion to each other, and
the first protrusion protrudes from the eleventh bent portion.

3. The display device of claim 2, wherein the third electrode further comprises:
a second main portion on the second electrode; and
a second protrusion protruding from the second main portion,
wherein the first protrusion is arranged to be connected to a top surface of the eleventh bent portion and protrudes into a region located between the first main portion and the second main portion.

4. The display device of claim 2, wherein the first main portion further comprises a thirteenth main portion and a twelfth bent portion between the twelfth main portion and the thirteenth main portion and connecting the twelfth main portion and the thirteenth main portion to each other.

5. The display device of claim 4, wherein the twelfth bent portion is connected to one side of the thirteenth main portion, and
the first main portion further comprises a thirteenth bent portion connected to the other side of the thirteenth main portion.

6. The display device of claim 1, wherein a light transmittance of the second electrode is greater than that of the third electrode, and
a light reflectivity of the third electrode is greater than that of the second electrode.

7. The display device of claim 1, wherein the display area comprises a first region corresponding to a first portion of the display area and a second region corresponding to a second portion of the display area,
the first main portion comprises an eleventh bent portion, a twelfth bent portion, and a twelfth main portion between the eleventh bent portion and the twelfth bent portion,
the first protrusion comprises a first side surface having a selected angle with the twelfth main portion and a second side surface having a selected angle with the twelfth main portion, and
the selected angle between the first side surface of the first protrusion with the twelfth main portion is different in the first region and the second region.

8. The display device of claim 7, wherein in the first region, the first side surface of the first protrusion has a first angle with the twelfth main portion,
in the second region, the first side surface of the first protrusion has a second angle with the twelfth main portion, and
the first angle is greater than the second angle.

9. The display device of claim 8, wherein the first region is closer to a center of the display area than the second region.

10. The display device of claim 8, wherein the first angle and the second angle are acute angles.

11. The display device of claim 7, wherein in the first region, the second side surface of the first protrusion has a third angle with the twelfth main portion,
in the second region, the second side surface of the first protrusion has a fourth angle with the twelfth main portion, and
the third angle is less than the fourth angle.

12. The display device of claim 11, wherein the third angle and the fourth angle are obtuse angles.

13. The display device of claim 1, wherein the third electrode comprises an opening overlapping the second electrode.

14. The display device of claim 13, wherein the display area comprises a first region corresponding to a first portion of the display area and a second region corresponding to a second portion of the display area,
the first main portion comprises an eleventh bent portion, a twelfth bent portion, and a twelfth main portion between the eleventh bent portion and the twelfth bent portion, and
an area of a region where the first protrusion overlaps the second electrode in a plane direction of the display area is different in the first region and the second region.

15. The display device of claim 9, wherein an area of a region where the first protrusion overlaps the second electrode in a plane direction of the display area is smaller in the first region than in the second region.

16. An electronic device comprising:
a processor configured to provide an image signal;
a display module configured to receive the image signal from the processor to display an image; and
a power module configured to supply power to the display module,
wherein the display module comprises:
a substrate on which a display area is defined;
a reflective electrode on the substrate;
an optical auxiliary layer on the reflective electrode;
a first electrode on the optical auxiliary layer;
a light emitting stack on the first electrode;
a second electrode on the light emitting stack; and
a third electrode on the second electrode,
wherein the third electrode comprises:
a first main portion on the second electrode; and
a first protrusion protruding from the first main portion.

17. The electronic device of claim 16, wherein a light transmittance of the second electrode is greater than that of the third electrode, and
a light reflectivity of the third electrode is greater than that of the second electrode.

18. The electronic device of claim 16, wherein the display area comprises a first region corresponding to a first portion of the display area and a second region corresponding to a second portion of the display area,
the first main portion comprises an eleventh bent portion, a twelfth bent portion, and a twelfth main portion between the eleventh bent portion and the twelfth bent portion,
the first protrusion comprises a first side surface having a selected angle with the twelfth main portion and a second side surface having a selected angle with the twelfth main portion, and
the selected angle between the first side surface of the first protrusion with the twelfth main portion is different in the first region and the second region.

19. The electronic device of claim 18, wherein in the first region, the first side surface of the first protrusion has a first angle with the twelfth main portion,
in the second region, the first side surface of the first protrusion has a second angle with the twelfth main portion, and
the first angle is greater than the second angle.

20. The electronic device of claim 16, wherein the third electrode comprises an opening overlapping the second electrode.
